(19) United States
(12) Patent Application Publication
(10) Pub. No.: US 2026/0268819 A1
(43) Pub. Date: Sep. 10, 2026

(54) ELECTRONIC APPARATUS AND METHOD FOR CONTROLLING ELECTRONIC APPARATUS

(71) Applicant: Sharp Display Technology Corporation, Kameyama City, Mie (JP)

(72) Inventors: Tatsuhiko SUYAMA, Kameyama City, Mie (JP); Yoshitaka ORITA, Kameyama City, Mie (JP); Shunsuke NOICHI, Kameyama City, Mie (JP); Noriyuki TANAKA, Kameyama City, Mie (JP); Kazuo NAKAMURA, Kameyama City, Mie (JP)

(21) Appl. No.: 19/122,382

(22) PCT Filed: Oct. 27, 2022
(86) PCT No.: PCT/JP2022/040091

§ 371 Date: Apr. 18, 2025

(51) Int. Cl. G09G 3/00; G01K 7/00; G01R 19/00; G09G 3/20; G09G 3/3208

(52) U.S. Cl. CPC G09G 3/006; G01K 7/00; G01R 19/0092; G09G 3/2007; G09G 3/3208; G09G 2320/041; G09G 2320/045; G09G 2320/048

(57) ABSTRACT

An electronic device includes a display portion that includes a pixel including a self-light-emitting element, a first heating element that generates heat in accordance with a value of a first current flowing outside the display portion, and a control unit that estimates, using a value of the first current, a temperature distribution of the display portion.

### TECHNICAL FIELD

The disclosure relates to an electronic device and a method for controlling an electronic device.

### BACKGROUND ART

In the related art, for example, in order to compensate for deterioration of a self-light-emitting element, a temperature distribution of a display portion is obtained.

In the technique disclosed in PTL 1, the temperature distribution is obtained using a temperature sensor. In the technique disclosed in PTL 2, based on luminance information in image data corresponding to a pixel region including at least one pixel, temperatures of pixels occupying the pixel region and a peripheral region thereof are estimated.

### CITATION LIST

### Patent Literature

PTL 1: JP 2021-135445 A
PTL 2: JP 2011-203314 A

### SUMMARY

### Technical Problem

In the technique disclosed in PTL 1, since a large number of temperature sensors are required, an increase in cost is a problem.

In the technique disclosed in PTL 2, since it is difficult to reflect heat generation of a heating element (for example, a battery and an integrated circuit) in a temperature estimation result, the accuracy of an obtained temperature distribution is low.

### Solution to Problem

An electronic device according to an aspect of the disclosure includes a display portion that includes a pixel including a self-light-emitting element; a first heating element that generates heat in accordance with a value of a first current flowing outside the display portion; and a control unit that estimates, using a value of the first current, a temperature distribution of the display portion.

### Advantageous Effects of Disclosure

According to an aspect of the disclosure, it is possible to reduce the cost and obtain a highly accurate temperature distribution.

### BRIEF DESCRIPTION OF DRAWINGS

FIG. 1 is a block diagram illustrating a schematic configuration of an electronic device according to an aspect of the disclosure.

FIG. 2 is a plan view illustrating an arrangement example of a first heating element, a second heating element, and a third heating element.

FIG. 3 shows deterioration compensation data (an example) when the input gray scale is 128 gray scale.

FIG. 4 is a diagram for explaining an estimation method of a temperature distribution of a display portion according to a first embodiment of the disclosure.

FIG. 5 is a diagram for explaining an estimation method of a temperature distribution of a display portion according to a second embodiment of the disclosure.

FIG. 6 shows an estimation result of the temperature distribution of the display portion when the value of a first current is 100 mA and the value of a second current is 10 mA.

FIG. 7 shows an example of the relationship of the value of the first current with respect to the elapsed time, the moving average value of the first current with respect to the elapsed time, and the temperature of the display portion corresponding to the first heating element with respect to the elapsed time.

### DESCRIPTION OF EMBODIMENTS

Embodiments for implementing the disclosure will be described. For convenience of description, members having the same functions as members described earlier may be denoted by the same reference numerals and signs, and the description thereof will not be repeated.

### First Embodiment

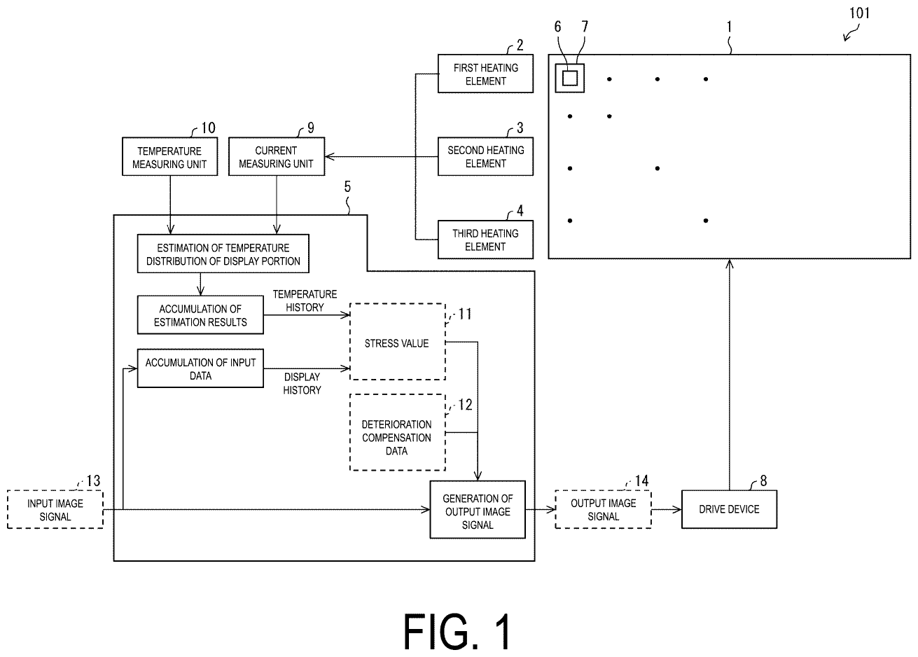

FIG. 1 is a block diagram illustrating a schematic configuration of an electronic device 101 according to an aspect of the disclosure. The electronic device 101 includes a display portion 1, a first heating element 2, a second heating element 3, a third heating element 4, and a control unit 5. Examples of the electronic device 101 include a display device, a personal computer, a tablet, a smartphone, a television receiver, and a digital signage.

The display portion 1 displays images. Examples of the display portion 1 include a display portion that performs display using an OLED (organic light-emitting diode) and a display portion that performs display using a QLED (quantum dot light-emitting diode). The display portion 1 includes a large number of pixels 7, each including a self-light-emitting element 6. The self-light-emitting element 6 may be an OLED or a QLED.

The first heating element 2 generates heat in accordance with the value of a first current flowing outside the display portion 1. The second heating element 3 generates heat in accordance with the value of a second current flowing outside the display portion 1. The third heating element 4 generates heat in accordance with the value of a third current flowing outside the display portion 1. Each of the first heating element 2, the second heating element 3, and the third heating element 4 may perform an electrical operation, and specifically may supply power or be supplied with power. Examples of each of the first heating element 2, the second heating element 3, and the third heating element 4 include various electronic circuits such as an integrated circuit, and a battery. The electronic device 101 includes a battery, a central processing unit (CPU), and a driver circuit that drives the pixels 7. Each of the first heating element 2, the second heating element 3, and the third heating element 4 may be any one of the battery, the CPU, and the driver circuit. The first heating element 2, the second heating element 3 and the third heating element 4 can be interpreted as three heating elements. The number of heating elements is not limited to three, and may be any number.

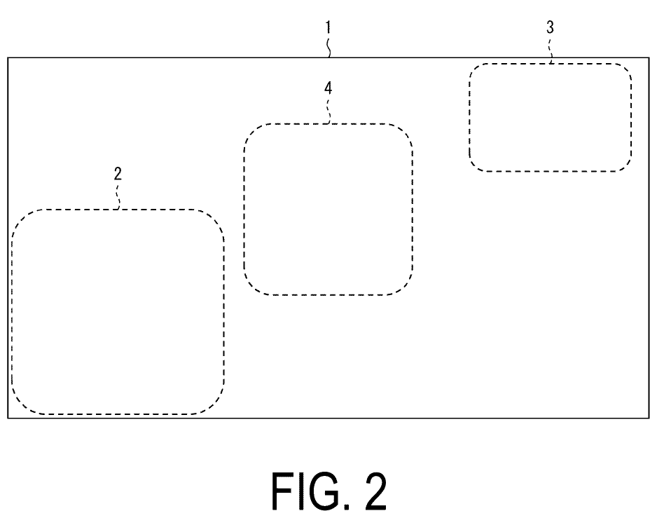

Each of the first heating element 2, the second heating element 3, and the third heating element 4 is disposed at or near the display portion 1. FIG. 2 is a plan view illustrating an arrangement example of the first heating element 2, the second heating element 3, and the third heating element 4. As illustrated in FIG. 2, each of the first heating element 2, the second heating element 3, and the third heating element 4 may be disposed on the back face of the display portion 1, in other words, may overlap the display portion 1.

The control unit 5 estimates the temperature distribution of the display portion 1 using the value of the first current. Examples of the first current include a current flowing into the first heating element 2 and a current flowing out of the first heating element 2.

The control unit 5 may estimate a first temperature distribution, which is a constituent element of the temperature distribution of the display portion 1, using the value of the first current. The first temperature distribution corresponds to the first heating element 2 in the temperature distribution of the display portion 1, and can be roughly interpreted as being generated using the first heating element 2 as a heat source.

The control unit 5 may estimate a second temperature distribution, which is a constituent element of the temperature distribution of the display portion 1, using the value of the second current. Examples of the second current include a current flowing into the second heating element 3 and a current flowing out of the second heating element 3. The second temperature distribution corresponds to the second heating element 3 in the temperature distribution of the display portion 1, and can be roughly interpreted as being generated using the second heating element 3 as a heat source.

The control unit 5 may estimate a third temperature distribution, which is a constituent element of the temperature distribution of the display portion 1, using the value of the third current. Examples of the third current include a current flowing into the third heating element 4 and a current flowing out of the third heating element 4. The third temperature distribution corresponds to the third heating element 4 in the temperature distribution of the display portion 1, and can be roughly interpreted as being generated using the third heating element 4 as a heat source.

The control unit 5 may estimate the temperature distribution of the display portion 1 by combining the first temperature distribution, the second temperature distribution, and the third temperature distribution.

The control unit 5 can estimate the temperature distribution of the display portion 1 without using a temperature sensor. Therefore, in the electronic device 101, since the number of temperature sensors can be reduced, it is possible to reduce the cost.

The control unit 5 reflects the heat generation of the first heating element 2, the second heating element 3, and the third heating element 4 in the temperature estimation result. Therefore, in the electronic device 101, a highly accurate temperature distribution can be obtained.

The control unit 5 may estimate the temperature distribution of the display portion 1 on the basis of information indicating the relationship between the value of the first current and the temperature distribution of the display portion 1. The information may be in the form of a table summarizing the relationship. The information may be stored in the control unit 5 in advance.

The electronic device 101 further includes a drive device (driver circuit) 8 of the display portion 1, a current measuring unit 9, and a temperature measuring unit 10. The electronic device 101 may include a display panel including the display portion 1 and the drive device 8.

The control unit 5 stores a stress value 11 and deterioration compensation data 12 for each of the self-light-emitting elements 6 of the large number of pixels 7.

The stress value 11 is an index indicating an integrated load of the self-light-emitting element 6. The stress value 11 is calculated from the display history (light emission luminance and light emission time) obtained by accumulating the input data and a temperature history obtained by accumulating the estimation result of the temperature distribution of the display portion 1. The input data is data indicated by an input image signal 13. As the stress value 11 increases, the degree of deterioration of the self-light-emitting element 6 also increases.

The current measuring unit 9 measures the value of the first current, the value of the second current, and the value of the third current. The current measuring unit 9 may be externally attached to the display portion 1. The term “being externally attached to the display portion 1” means not being incorporated in the display portion 1. The current measuring unit 9 may be provided in the display panel described above, for example, may be provided in the drive device 8. The electronic device 101 may include a display panel including the display portion 1 and a circuit substrate connected to the display panel, and the current measuring unit 9 may be provided on the circuit substrate.

The temperature measuring unit 10 measures its ambient temperature. For example, the temperature measuring unit 10 may measure the temperature of the environment in which the electronic device 101 is placed. The temperature measuring unit 10 is not an essential member in the electronic device 101.

The control unit 5 estimates the first temperature distribution using the value of the first current measured by the current measuring unit 9. The control unit 5 may estimate the first temperature distribution on the basis of first information indicating a relationship between the value of the first current and the first temperature distribution. The first information may be in the form of a table summarizing the relationship. The first information may be stored in the control unit 5 in advance.

The control unit 5 estimates the second temperature distribution using the value of the second current measured by the current measuring unit 9. The control unit 5 may estimate the second temperature distribution on the basis of second information indicating a relationship between the value of the second current and the second temperature distribution. The second information may be in the form of a table summarizing the relationship. The second information may be stored in the control unit 5 in advance.

The control unit 5 estimates the third temperature distribution using the value of the third current measured by the current measuring unit 9. The control unit 5 may estimate the third temperature distribution on the basis of third information indicating a relationship between the value of the third current and the third temperature distribution. The third information may be in the form of a table summarizing the relationship. The third information may be stored in the control unit 5 in advance.

The control unit 5 estimates the temperature distribution of the display portion 1 by combining the first temperature distribution, the second temperature distribution, the third temperature distribution, and the temperature measurement result by the temperature measuring unit 10.

In other words, the control unit 5 estimates the temperature distribution of the display portion 1 on the basis of the information indicating the relationship between the value of the first current and the temperature distribution of the display portion 1. The control unit 5 obtains the above-described temperature history by accumulating the estimation result of the temperature distribution of the display portion 1 per unit time.

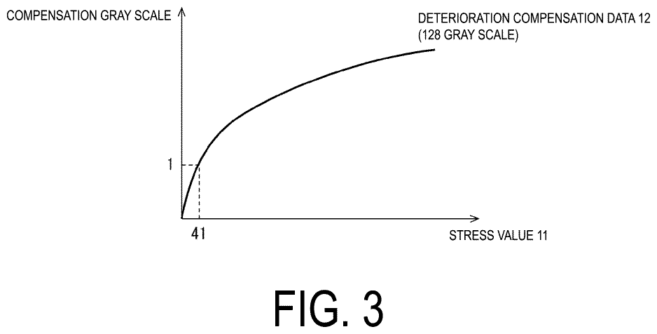

The deterioration compensation data 12 is data that is prepared for each input gray scale (for example, 0 to 255 gray scale) indicated by the input data and associates the stress value 11 with a compensation gray scale. FIG. 3 shows, as an example, the deterioration compensation data 12 in a case in which the input gray scale is 128 gray scale. When the input gray scale is 0 gray scale (non-lighting), the compensation gray scale is 0 regardless of the stress value 11.

The control unit 5 generates an output image signal 14. The output image signal 14 is calculated by using the input gray scale indicated by the input data and the compensation gray scale corresponding to the input gray scale defined by the deterioration compensation data 12. For example, referring to FIG. 3, in a certain pixel 7 of the display portion 1, when the input gray scale is 128 gray scale and the stress value 11 is a numerical value “41”, the compensation gray scale is 1 gray scale, so that the output image signal 14 is 129 (128+1) gray scale.

The drive device 8 drives the display portion 1 to cause a gray scale defined by the output image signal 14 for each pixel 7 to be displayed.

The control unit 5 may correct the image signal supplied to the pixel 7 on the basis of the temperature distribution of the display portion 1. For example, the control unit 5 corrects the input image signal 13 by using the stress value 11 and the deterioration compensation data 12 to generate the output image signal 14.

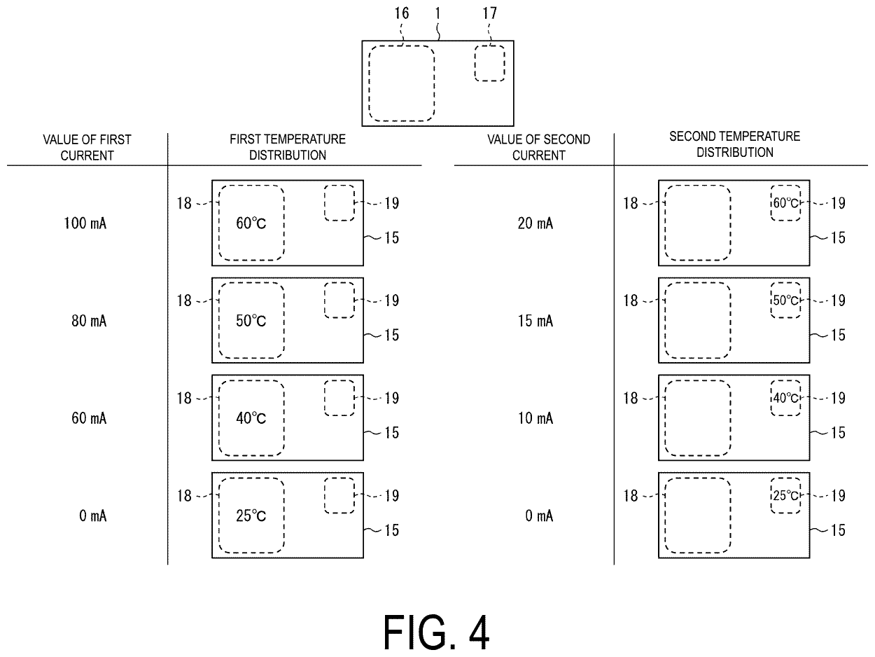

FIG. 4 is a diagram for explaining an estimation method of the temperature distribution of the display portion 1 according to the first embodiment of the disclosure. A temperature distribution display region 15 is a region in which the temperature distribution of the display portion 1 is shown, and positionally corresponds to the display portion 1 in a one-to-one manner in a plan view.

The display portion 1 includes a first region 16 and a second region 17. The first region 16 is a region corresponding to the position of the first heating element 2, and more specifically, is a region in which a change in temperature of the display portion 1 due to heat generation of the first heating element 2 is predicted. The second region 17 is a region corresponding to the position of the second heating element 3, and more specifically, is a region in which a change in the temperature of the display portion 1 due to heat generation of the second heating element 3 is predicted.

The temperature distribution display region 15 includes a third region 18 and a fourth region 19. The third region 18 is a region in which the temperature of the first region 16 is indicated, and positionally corresponds to the first region 16 in a one-to-one manner in a plan view. The fourth region 19 is a region in which the temperature of the second region 17 is indicated, and positionally corresponds to the second region 17 in a one-to-one manner in a plan view.

The control unit 5 may estimate the temperature of the first region 16 corresponding to the arrangement of the first heating element 2 in the display portion 1 as the first temperature distribution by using the value of the first current. For example, the information indicated by the first temperature distribution is expressed as follows. When the first temperature distribution is shown in the temperature distribution display region 15, the temperature displayed in the third region 18 corresponds to the temperature of the first region 16.

When the value of the first current is 100 mA, the temperature of the first region 16 is 60° C.

When the value of the first current is 80 mA, the temperature of the first region 16 is 50° C.

When the value of the first current is 60 mA, the temperature of the first region 16 is 40° C.

When the value of the first current is 0 mA, the temperature of the first region 16 is 25° C.

The control unit 5 may estimate the temperature of the second region 17 corresponding to the arrangement of the second heating element 3 in the display portion 1 as the second temperature distribution by using the value of the second current. For example, the information indicated by the second temperature distribution is expressed as follows. When the second temperature distribution is shown in the temperature distribution display region 15, the temperature displayed in the fourth region 19 corresponds to the temperature of the second region 17.

When the value of the second current is 20 mA, the temperature of the second region 17 is 60° C.

When the value of the second current is 15 mA, the temperature of the second region 17 is 50° C.

When the value of the second current is 10 mA, the temperature of the second region 17 is 40° C.

When the value of the second current is 0 mA, the temperature of the second region 17 is 25° C.

The control unit 5 may estimate the temperature of a region corresponding to the arrangement of the third heating element 4 in the display portion 1 as the third temperature distribution by using the value of the third current. The control unit 5 may estimate the temperature distribution of the display portion 1 by combining the temperatures of the regions corresponding to the arrangements of the plurality of heating elements in the display portion 1 estimated using the values of the currents corresponding to the plurality of heating elements provided in the electronic device 101.

### Second Embodiment

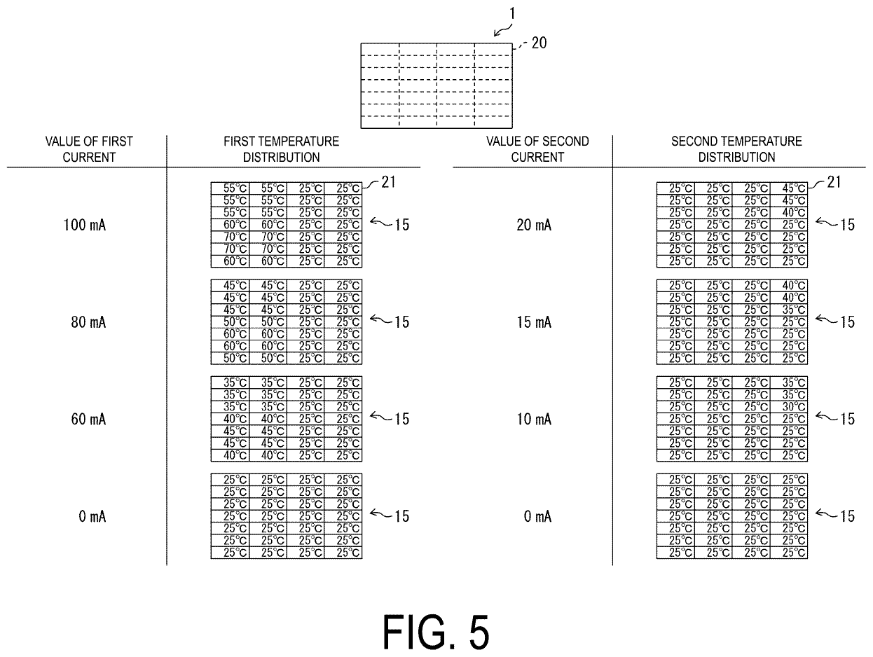

FIG. 5 is a diagram for explaining an estimation method of the temperature distribution of the display portion 1 according to a second embodiment of the disclosure.

The display portion 1 includes a plurality of unit regions 20. In other words, the control unit 5 virtually divides the display portion 1 into the plurality of unit regions 20. In FIG. 5, the plurality of unit regions 20 are arranged in a matrix (7 rows and 4 columns), and the number of unit regions 20 is 28 in FIG. 5, but the arrangement of the plurality of unit regions 20 and the number of unit regions 20 are not particularly limited. All of the plurality of unit regions 20 may have the same size, or the plurality of unit regions 20 may include two or more unit regions 20 having sizes different from each other.

The temperature distribution display region 15 includes a plurality of unit regions 21. The plurality of unit regions 21 positionally correspond to the plurality of unit regions 20 in a one-to-one manner in a plan view, respectively.

The control unit 5 may estimate the temperature corresponding to the first heating element 2 in each of the plurality of unit regions 20 as the first temperature distribution by using the value of the first current. The control unit 5 may estimate the temperature corresponding to the second heating element 3 in each of the plurality of unit regions 20 as the second temperature distribution by using the value of the second current. When each of the first temperature distribution and the second temperature distribution is shown in the temperature distribution display region 15, the temperature displayed for each of the plurality of unit regions 21 corresponds to the temperature for each of the plurality of unit regions 20.

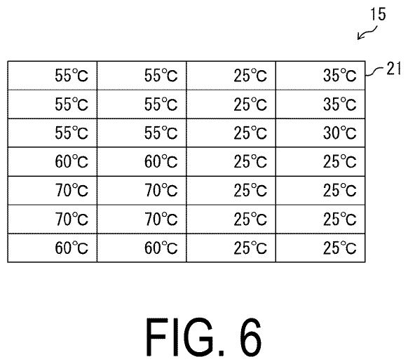

FIG. 6 shows the estimation result of the temperature distribution of the display portion 1 when the value of the first current is 100 mA and the value of the second current is 10 mA.

The control unit 5 may estimate the temperature corresponding to both the first heating element 2 and the second heating element 3 for each of the plurality of unit regions 20 by Equation (1). The atmospheric temperature may be a temperature of an environment in which the electronic device 101 is placed, or may be a temperature of a member that is considered as not generating heat in the electronic device 101.

$$( Temperature corresponding to first heating element 2 ) + ( temperature corresponding to second heating element 3 ) - ( atmospheric temperature ) \qquad ( 1 )$$

That is, the control unit 5 may estimate the temperature corresponding to both the first heating element 2 and the second heating element 3 of each of the unit regions 20 as a value obtained by subtracting the atmospheric temperature from the sum of the temperature corresponding to the first heating element 2 and the temperature corresponding to the second heating element 3 by using the value of the first current and the value of the second current.

It is assumed that the electronic device 101 includes n heating elements. For each of the n heating elements, the control unit 5 estimates the temperature corresponding to the heating element in each of the plurality of unit regions 20 by using the value of the current corresponding to the heating element. Examples of the current corresponding to the heating element include a current flowing into the heating element and a current flowing out of the heating element.

The atmospheric temperature is TO. The temperature corresponding to the first heating element is T1, the temperature corresponding to the second heating element is T2, . . . , the temperature corresponding to the (n-1)th heating element is Tm, and the temperature corresponding to the nth heating element is Tn. The control unit 5 may estimate the temperatures corresponding to all of the n heating elements for each of the plurality of unit regions 20 by Equation (2). In other words, the control unit 5 may estimate the temperature for each of the plurality of unit regions 20 by Equation (3).

$$T 0 + ( T 1 - T 0 ) + ( T 2 - T 0 ) + ... ( Tm - T 0 ) + ( Tn - T 0 ) = ( T 1 + T 2 + … Tm + Tn ) - T 0 \times ( n - 1 ) \qquad ( 2 )$$

$$( Total sum of temperatures corresponding to n heating elements ) - ( atmospheric temperature ) \times ( n - 1 ) \qquad ( 3 )$$

Equation (1) corresponds to the case where n=2 in Equation (3). (Atmospheric temperature) in Equation (1) is strictly “(atmospheric temperature)×(2-1)”.

The control unit 5 may correct the image signal supplied to the pixel 7 on the basis of the estimated temperature of the unit region 20 corresponding to the pixel 7 among the plurality of unit regions 20. For the correction method, refer to FIG. 1 and FIG. 3 described above and the description thereof.

According to the method for estimating the temperature distribution of the display portion 1 according to the second embodiment of the disclosure, the following can be said as compared with the method for estimating the temperature distribution of the display portion 1 according to the first embodiment of the disclosure. Since the display portion 1 is virtually subdivided into the plurality of unit regions 20, the accuracy of the temperature distribution of the display portion 1 can be improved.

The control unit 5 may estimate the temperature corresponding to the third heating element 4 in each of the plurality of unit regions 20 as the third temperature distribution by using the value of the third current. The control unit 5 may estimate the temperature distribution of the display portion 1 by combining the temperatures that correspond to the plurality of heating elements in each of the plurality of unit regions 20 and are estimated using the values of the currents corresponding to the plurality of heating elements provided in the electronic device 101, for example, in the manner of Equation (3).

### Third Embodiment

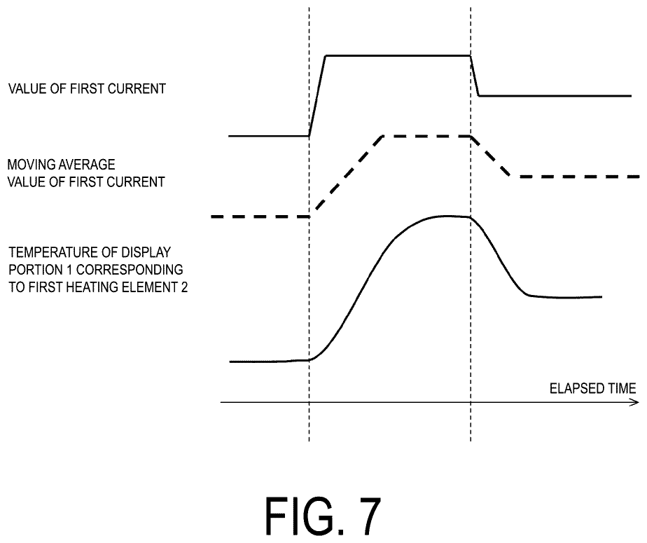

FIG. 7 shows an example of the relationship of the value of the first current with respect to the elapsed time, the moving average value of the first current with respect to the elapsed time, and the temperature of the display portion 1 corresponding to the first heating element 2 with respect to the elapsed time. In order to simplify the chart, in FIG. 7, the horizontal axis represents time, and the vertical axis represents current value and temperature. The elapsed time, the value of the first current, the moving average value of the first current, and the temperature of the display portion 1 corresponding to the first heating element 2 are all in arbitrary units.

In general, when the first current flows, the temperature of the display portion 1 corresponding to the first heating element 2 does not rise immediately. Similarly, when the first current stops flowing, the temperature of the display portion 1 corresponding to the first heating element 2 does not decrease immediately. The temperature change of the display portion 1 corresponding to the first heating element 2 has a time lag with respect to the change in the value of the first current.

Therefore, the control unit 5 may replace the value of the first current with respect to the elapsed time with a moving average value of the first current with respect to the elapsed time. Then, the control unit 5 may estimate the temperature of the display portion 1 corresponding to the first heating element 2 and thus the temperature distribution of the display portion 1 by using the moving average value of the first current with respect to the elapsed time. As such, the time lag of the temperature change of the display portion 1 corresponding to the first heating element 2 can be made smaller than that of the change in the value of the first current, so that the accuracy of the temperature distribution of the display portion 1 can be improved.

In the same manner as that described above, the control unit 5 may estimate the temperature of the display portion 1 corresponding to the second heating element 3 by using the moving average value of the second current with respect to the elapsed time, or may estimate the temperature of the display portion 1 corresponding to the third heating element 4 by using the moving average value of the third current with respect to the elapsed time.

### Fourth Embodiment

A control method of the electronic device 101, which corresponds to the operation of the control unit 5, is also included within the scope of the disclosure. The control method of the electronic device 101 is a control method of the electronic device 101 including the display portion 1 including the self-light-emitting element 6, and the first heating element 2 that generates heat in accordance with the value of the first current flowing outside the display portion 1, and is a control method of estimating a temperature distribution of the display portion 1 by using the value of the first current, and driving the display portion 1 on the basis of an estimation result.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1 Display portion
2 First heating element
3 Second heating element
4 Third heating element
5 Control unit
6 Self-light-emitting element
7 Pixel
8 Drive device (driver circuit)
9 Current measuring unit
10 Temperature measuring unit
11 Stress value
12 Deterioration compensation data
13 Input image signal
14 Output image signal
15 Temperature distribution display region
16 First region
17 Second region
18 Third region
19 Fourth region
20, 21 Unit region
101 Electronic device

1. An electronic device comprising:
a display portion including a pixel including a self-light-emitting element;
a first heating element configured to generate heat in accordance with a value of a first current flowing outside the display portion; and
a control unit configured to estimate, using a value of the first current, a temperature distribution of the display portion.

2. The electronic device according to claim 1,
wherein the control unit corrects an image signal supplied to the pixel, based on the temperature distribution.

3. The electronic device according to claim 1,
wherein the control unit estimates the temperature distribution, based on information indicating a relationship between the value of the first current and the temperature distribution.

4. The electronic device according to claim 1,
wherein the control unit estimates, using a value of the first current, a temperature of a region corresponding to an arrangement of the first heating element in the display portion.

5. The electronic device according to claim 1,
wherein the display portion includes a plurality of unit regions, and
the control unit estimates, using the value of the first current, a temperature corresponding to the first heating element in each of the plurality of unit regions.

6. The electronic device according to claim 5, further comprising:
a second heating element configured to generate heat in accordance with a value of a second current flowing outside the display portion,
wherein the control unit estimates, using the value of the second current, a temperature corresponding to the second heating element in each of the plurality of unit regions, and estimates a temperature corresponding to both the first heating element and the second heating element in each of the unit regions as a value obtained by subtracting an atmospheric temperature from a sum of the temperature corresponding to the first heating element and the temperature corresponding to the second heating element.

7. The electronic device according to claim 5,
wherein the control unit corrects an image signal supplied to the pixel, based on an estimated temperature of a unit region corresponding to the pixel among the plurality of unit regions.

8. The electronic device according to claim 1,
wherein the control unit estimates the temperature distribution, using a moving average value of the first current with respect to an elapsed time.

9. The electronic device according to claim 1, further comprising:
a current measuring unit configured to measure the value of the first current.

10. The electronic device according to claim 9, further comprising:
a display panel including the display portion; and
a circuit substrate connected to the display panel,
wherein the current measuring unit is provided on the circuit substrate.

11. The electronic device according to claim 1, further comprising:
a battery, a CPU, and a driver circuit configured to drive the pixel,
wherein the first heating element is any one of the battery, the CPU, and the driver circuit.

12. A method for controlling an electronic device including a display portion including a self-light-emitting element, and a first heating element configured to generate heat in accordance with a value of a first current flowing outside the display portion, the method comprising:
estimating a temperature distribution of the display portion, using the value of the first current, and driving the display portion, based on an estimation result.
